(19) United States
(12) Patent Application Publication
(10) Pub. No.: US 2015/0382460 A1
(43) Pub. Date: Dec. 31, 2015

(54) PRINTED CIRCUIT BOARD (PCB) WITH WRAPPED CONDUCTOR

(71) Applicant: Avago Technologies General IP (Singapore) Pte. Ltd., Singapore (SG)

(72) Inventor: Jack Vasken Ajoian, Campbell, CA (US)

(21) Appl. No.: 14/318,156

(22) Filed: Jun. 27, 2014

(51) Int. Cl. H05K 1/09; H05K 1/03; H05K 3/00; C23C 28/02; H05K 3/46; C25D 7/00; C25D 5/34; H05K 1/02; H05K 3/06

(52) U.S. Cl. CPC H05K 1/09; H05K 1/025; H05K 1/0296; H05K 1/034; H05K 3/0091; H05K 3/067; H05K 3/46; C25D 7/00; H05K 3/4608; C25D 5/34; C23C 28/023; H05K 2201/015; H05K 2203/072; H05K 2203/0723

(57) ABSTRACT

A printed circuit board (PCB) includes a wrapped conductor enabling transmission of a radio frequency (RF) signal, the wrapped conductor including a conductor core and a conductive wrap disposed on top and side surfaces of the conductor core. The PCB further includes a top dielectric layer disposed on the conductive wrap of the wrapped conductor, at least partially embedding the wrapped conductor. Resistivity of the conductive wrap is less than resistivity of the conductor core, such that a majority of RF power of the RF signal is propagated through the conductive wrap.

### BACKGROUND

A conventional printed circuit board (PCB) may have embedded conductors for transmitting electrical signals, such as radio frequency (RF) signals, as well as for providing power and ground connections. The embedded conductors, which may be part of a conductor pattern, are typically formed of copper disposed on a first dielectric layer, and then covered by a second dielectric layer. The first and second dielectric layers may be referred to as “prepreg,” and the PCB with embedded (copper) conductors between the first and second dielectric layers may be referred to as a “build-up substrate.”

Currently, when the embedded conductors are formed of copper, they are oxidized during the fabrication process to improve adhesion of the copper to the second dielectric layer during and after formation of the second dielectric layer (or, lamination process). Oxidation results in a thin, electrically resistive oxide layer formed on the copper conductors. Thus, using conventional oxidation, the electrical conductivity of the copper conductors can not be increased in standard PCB applications. As a practical matter, the only materials having better electrical conductivity than copper are silver and graphene. However, these materials are generally more expensive than copper, and more difficult to apply, pattern and etch when formed directly on a dielectric layer.

Therefore, there is a need for increased conductivity of embedded conductors in build-up substrates, while maintaining or improving adhesiveness between the embedded conductors and the dielectric layers of the PCB substrate.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 is a cross-sectional view of a printed circuit board (PCB) including an embedded wrapped conductor, according to a representative embodiment.

FIG. 2 is graph showing operating frequency of a radio frequency (RF) signal versus thickness of a conductive wrap of the embedded wrapped conductor, according to a representative embodiment.

FIG. 3 is a flow diagram illustrating a method of fabricating a PCB including an embedded wrapped conductor, according to a representative.

FIGS. 4A-4G are cross-sectional diagrams illustrating steps in a fabrication process of a PCB including an embedded wrapped conductor, according to representative embodiments.

FIG. 5 is a cross-sectional view of a PCB including a partially embedded wrapped conductor, according to a representative embodiment.

### DETAILED DESCRIPTION

In the following detailed description, for purposes of explanation and not limitation, example embodiments disclosing specific details are set forth in order to provide a thorough understanding of the present teachings. However, it will be apparent to one having ordinary skill in the art having the benefit of the present disclosure that other embodiments according to the present teachings that depart from the specific details disclosed herein remain within the scope of the appended claims. Moreover, descriptions of well-known apparatuses and methods may be omitted so as to not obscure the description of the example embodiments. Such methods and apparatuses are clearly within the scope of the present teachings.

The terminology used herein is for purposes of describing particular embodiments only, and is not intended to be limiting. The defined terms are in addition to the technical, scientific, or ordinary meanings of the defined terms as commonly understood and accepted in the relevant context.

The terms “a”, “an” and “the” include both singular and plural referents, unless the context clearly dictates otherwise. Thus, for example, “a device” includes one device and plural devices. The terms “substantial” or “substantially” mean to within acceptable limits or degree. The term “approximately” means to within an acceptable limit or amount to one of ordinary skill in the art. Relative terms, such as “above,” “below,” “top,” “bottom,” “upper” and “lower” may be used to describe the various elements' relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be below that element. Where a first device is said to be connected or coupled to a second device, this encompasses examples where one or more intermediate devices may be employed to connect the two devices to each other. In contrast, where a first device is said to be directly connected or directly coupled to a second device, this encompasses examples where the two devices are connected together without any intervening devices other than electrical connectors (e.g., wires, bonding materials, etc.).

As mentioned above, copper conductors, e.g., formed by patterning a copper layer disposed between first and second dielectric layers in a build-up substrate are currently oxidized to improve adhesion to the second dielectric layer during and after lamination. However, according to various embodiments, silver is plated onto the copper conductors in place of the thin oxide layer, effectively wrapping the exposed surfaces of the copper conductors in a silver layer or silver wrap, thereby increasing conductivity. The interface between the silver wrap and the second dielectric layer may be optimized, so that adhesion to the second dielectric layer is improved or not degraded. The silver may be plated onto the copper conductors using an immersion silver process, for example. In applications involving radio frequency (RF) signals, in particular, the increased conductivity may result from substantially all (e.g., about 98 percent) of the RF energy propagating on three skin depths the silver wrap, which is typically much smaller than the total cross-section of the copper conductor. Other skin depths may be incorporated without departing from the scope of the present teachings.

In accordance with a representative embodiment, a PCB includes a wrapped conductor enabling transmission of an RF signal, the wrapped conductor including a conductor core and a conductive wrap disposed on top and side surfaces of the conductor core. The PCB further includes a top dielectric layer disposed on the conductive wrap of the wrapped conductor, at least partially embedding the wrapped conductor. Resistivity of the conductive wrap is less than resistivity of the conductor core, such that a majority of RF power of the RF signal is propagated through the conductive wrap.

In accordance with another representative embodiment, a build-up substrate of a PCB includes a first dielectric layer; a copper conductor core disposed on a top surface of the first dielectric layer; and a plated silver conductive wrap disposed on top and side surfaces of the copper conductor core, the plated silver conductive wrap being configured to transmit a radio frequency (RF) signal. A second dielectric layer is disposed on exposed portions of the top surface of the first dielectric layer and the plated silver conductive wrap. A majority of RF power of the RF signal is propagated through the plated silver conductive wrap.

In accordance with another representative embodiment, a method is provided for fabricating a PCB having an embedded wrapped conductor. The method includes forming a seed layer on a first dielectric layer; forming a copper layer on the seed layer; patterning and etching the copper layer and the seed layer to form a copper conductor core; plating silver to exposed surfaces of the copper conductor; and forming a second dielectric layer on the first dielectric layer and the plated silver wrap to form the embedded wrapped conductor.

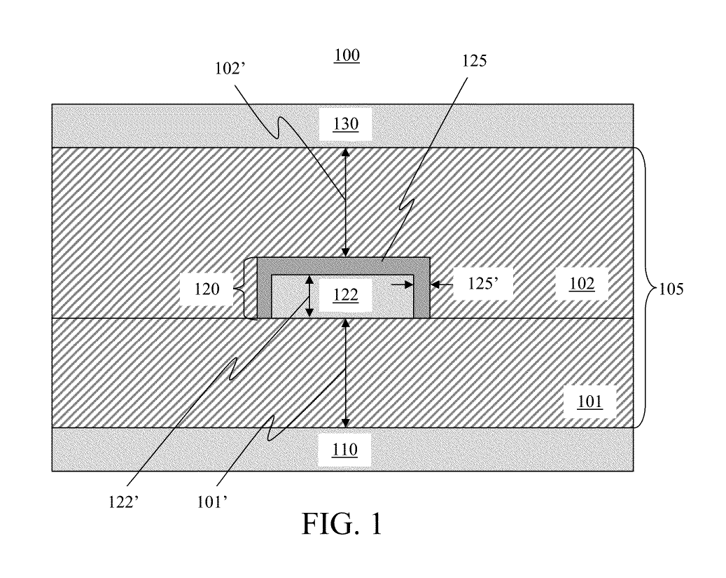

FIG. 1 is a cross-sectional view of a printed circuit board (PCB) including an embedded wrapped conductor, according to a representative embodiment.

Referring to FIG. 1, PCB 100 includes a substrate 105 including a first (bottom) dielectric layer 101 and a second (top) dielectric layer 102. In the depicted embodiment, the PCB 100 further includes a first (bottom) conductive layer 110, a second conductive layer, referred to as wrapped conductor 120 for purpose of discussion, and third (top) conductive layer 130. The wrapped conductor 120 is embedded between the first and second dielectric layers 101 and 102. In particular, the first dielectric layer 101 is formed on a top surface of the first conductive layer 110, the wrapped conductor 120 is disposed on a top surface of the first dielectric layer 101, the second dielectric layer 102 is disposed on top surfaces of the wrapped conductor 120 and the first dielectric layer 101, and the third conductive layer 130 is disposed on the top surface of the second dielectric layer 102 (which is also the top surface of the substrate 105). In this configuration, the first dielectric layer 101 and the second dielectric layer 102 fully embed the wrapped conductor 125.

One or both of the first and third conductive layers 110 and 130 may be a ground plane or power plane, for example. Also, although the first and third conductive layers 110 and 130 are referred to as “layers,” it is understood that this term may include conductive “patterns,” indicating the presence of multiple conductors, traces, pads and/or other circuitry, without departing from the scope of the present teachings. Likewise, for purposes of illustration and ease of description, the wrapped conductor 120 is shown as a single conductor, although it is understood that the wrapped conductor 120 may include multiple conductors and/or a conductive “pattern,” as mentioned above, without departing from the scope of the present teachings. The wrapped conductor 120 is embedded within the substrate 105 in that at least the top, bottom and side surfaces in the cross-sectional view are covered by the first and second dielectric layers 101 and 102. The wrapped conductor 120 enables transmission of an RF signal, for example.

In various embodiments, the first and second dielectric layers 101 and 102 (or “prepreg”) may be formed of glass reinforced epoxy, glass reinforced resin and/or organic material, such as FR-4 or polytetrafluoroethylene (Teflon®), for example. The first and second dielectric layers 101 and 102 may be formed of the same or different materials, as long as they adequately adhere to one another to create a durable, integrated substrate 105. The first and third conductor layers 110 and 130 may be formed of metal, such as copper (Cu), for example. The first and third conductor layers 110 and 130 likewise may be formed of the same or different materials. Of course, it is understood that the first and second dielectric layers 101 and 102 may be formed of any other compatible dielectric materials (or combinations thereof), and the first and third conductor layers 110 and 130 may be formed of any other compatible electrically conductive materials (or combinations thereof), without departing from the scope of the present teachings.

The wrapped conductor 120 includes a conductor core 122 and a conductive wrap 125 surrounding the conductor core 122 on three sides. That is, the conductor core 122 is formed on the top surface of the first dielectric layer 101 and the conductive wrap 125 is formed (e.g., electrolytically plated) on exposed surfaces of the inner conductor core 122. The second dielectric layer 102 may then be formed over the outer surface of the conductive wrap 125 of the wrapped conductor 120, as well as over exposed portions of the first dielectric layer 101. Also, the conductive wrap 125 assists in adhering the conductor core 122 to the second dielectric layer 102.

The conductive wrap 125 has a lower resistivity (p) than the conductor core 122, so that the majority of the RF power is conducted through the conductive wrap 125, as opposed to the conductor core 122. For example, the conductor core 122 may be formed of copper, which has a resistivity of about 1.68×10⁻⁸ ohm-meter, and the conductive wrap 125 may be formed of silver, which has a resistivity of about 1.59×10⁻⁸ ohm-meter. Thus, the silver conductive wrap 125 is about 5.4 percent more conductive than the copper conductor core 122, which increases speed and efficiency of transmitting the RF signal. Meanwhile, the copper conductor core 122 may maintain an impedance of about 50 ohms, which provides interface compatibility with most circuit designs, regardless of the presence of the silver conductive wrap 125.

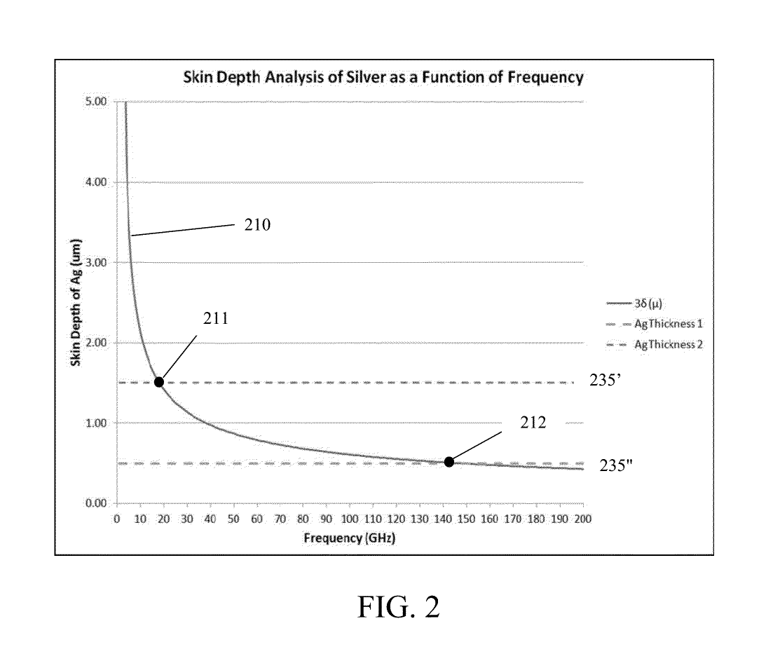

In the depicted embodiment, thickness 122′ of the copper conductor core 122 is approximately 15 μm, and thickness 125′ of the silver conductive wrap 125 is approximately 1.5 μm. The thickness of silver enables propagation of substantially all RF energy through the silver conductive wrap 125 for RF signals having a operating frequency of about 16 GHz and above, as discussed below with reference to FIG. 2. Also, for example, thickness 101′ of the first dielectric layer 101 below the wrapped conductor 120 and thickness 102′ of the second dielectric layer 102 above the wrapped conductor 120 may each be approximately 40 μm. Of course, the thicknesses and/or materials of the various layers and conductors may vary to provide unique benefits for any particular situation or to meet application specific design requirements of various implementations, as would be apparent to one skilled in the art.

In various embodiments, the thickness of the conductive wrap 125 is determined based on the portion of RF energy to be propagated through the conductive wrap 125 (as opposed to the conductor core 122) of the wrapped conductor 120. For example, in a representative embodiment, the thickness of the conductive wrap 125 is determined such that the about 98 percent of the RF energy is propagated through three skin depths of the material forming the conductive wrap 125. Skin depth (δ) of a material depends on the resistivity (ρ) of the conductive material (e.g., silver) in ohm-meters and the operating frequency (f) of the RF signal in Hertz, as provided by Equation (1):

δ=\sqrt{2ρ/2πfμ} (1)

Also in Equation (1), μ is the absolute magnetic permeability of the conductive material. The absolute magnetic permeability μ is equal to μ₀×μᵣ, where μ₀ is the permeability of free space (4π×10⁻⁷) and μᵣ is the relative permeability of the conductive material equal to 4π×10⁻⁷ henries/meter, which together may be assumed to be unity.

FIG. 2 is graph showing operating frequency of an RF signal (in GHz) versus thickness of a conductive wrap (in μm) required to conduct the RF signal within three skin depths of the conductive wrap material.

More particularly, for purposes of illustration, the material forming the conductive wrap 125 is silver, and curve 210 depicts the thickness of silver required to conduct at least 98 percent of the RF energy through three skin depths of silver at corresponding RF frequencies. Representative first and second thicknesses 235′ and 235″ of the silver conductive wrap 125 are depicted as corresponding dashed lines in FIG. 2. The first thickness 235′ of silver is about 1.50 μm and the second thickness 235″ is about 0.50 μm. As indicated by intersection 211 of curve 210 and the first thickness 225′, when the conductive wrap 125 has a thickness of about 1.5 μm, it will conduct at least about 98 percent of the RF energy within three skin depths for RF signals having fundamental frequencies of about 16 GHz and above. In comparison, as indicated by the intersection 212 of curve 210 and the second thickness 225″, when the conductive wrap 125 has a thickness of about 0.5 μm, it will conduct about 98 percent of the RF energy within three skin depths for RF signals having fundamental frequencies of about 143 GHz and above. In other words, the thicker the conductive wrap 125, the lower the RF frequencies it is capable of transmitting substantially within three skin depths.

When the RF frequency is known, the conductive wrap 125 may be designed more precisely to have a thickness capable of propagating about 98 percent of the RF energy of the corresponding RF signal within three skin depths, thus conserving the amount of material used to form the conductive wrap 125. Curve 210 would change based on factors such as the type of metal conductor (and corresponding resistivity) and/or frequencies of the RF signal. Also, the RF signal may operate over a range of potential frequencies, and the operating frequency for determining the skin depth of the conductive wrap material is the lowest frequency of the range of potential frequencies.

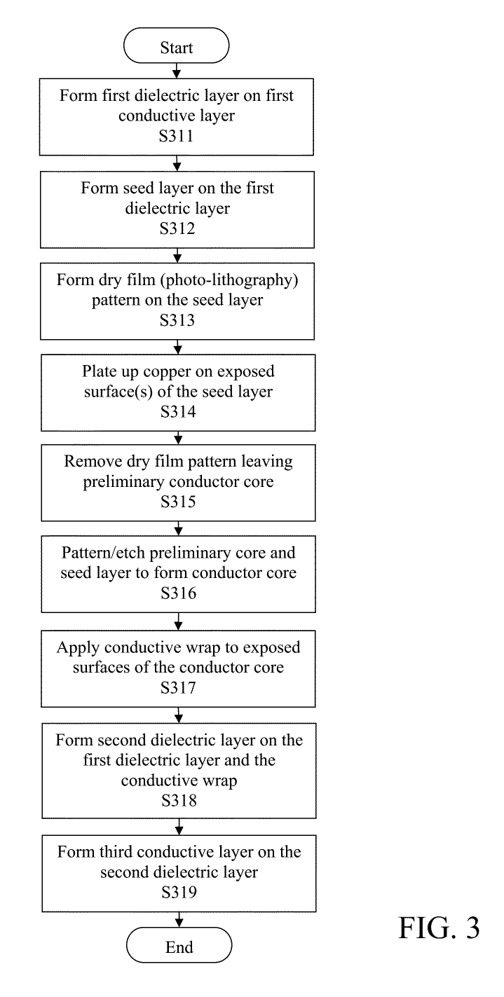

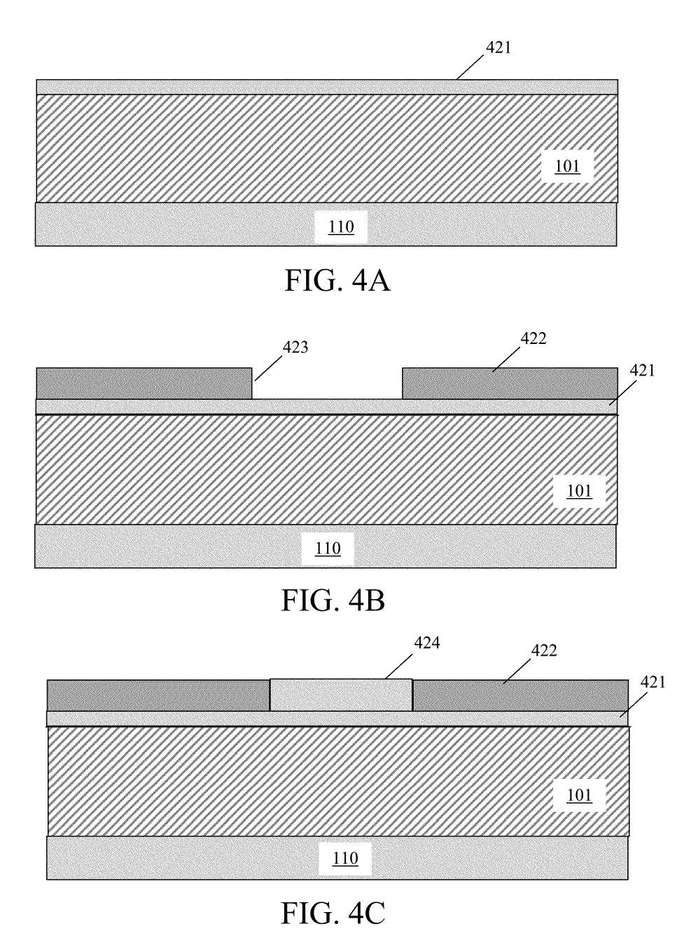

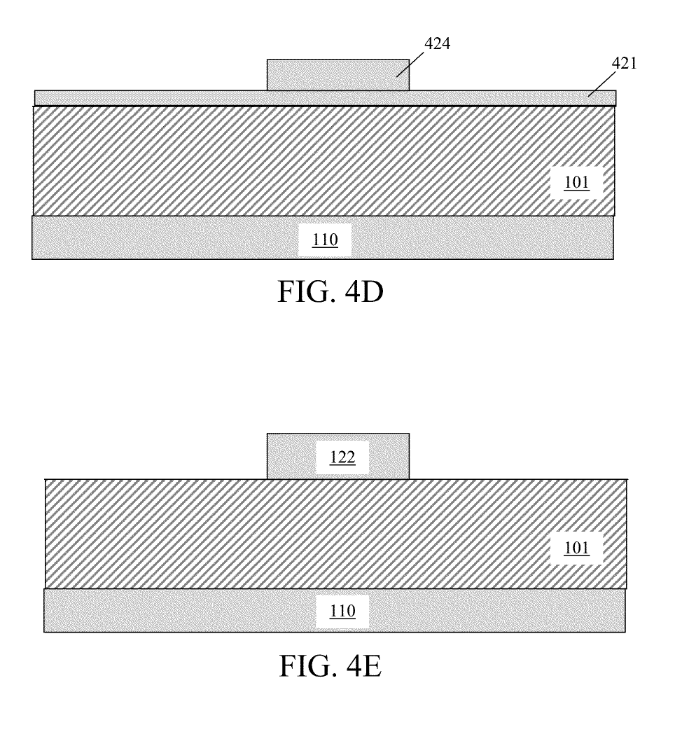

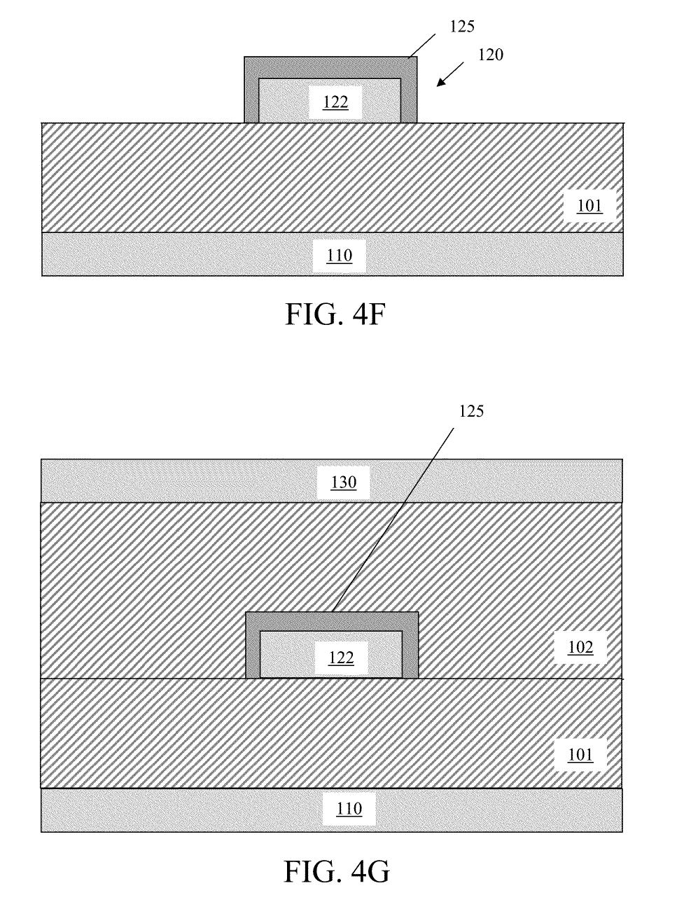

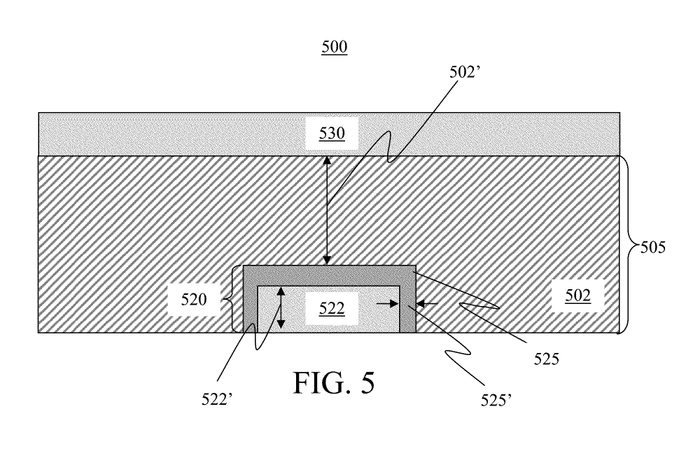

According to various embodiments, the PCB 100 may be fabricated using various techniques compatible with semiconductor processes. A non-limiting example of a fabrication process directed to representative PCB 100 is discussed below with reference to FIG. 3 and FIGS. 4A-4E. The various materials and order of application for forming the PCB 100 are discussed above with regard to FIG. 1.

FIG. 3 is a flow diagram illustrating a method of fabricating a PCB with an embedded wrapper conductor, according to a representative embodiment. FIGS. 4A-4E are cross-sectional diagrams illustrating the steps of the fabrication process of a PCB with an embedded conductor pattern, substantially corresponding to the operations depicted in FIG. 3, according to a representative embodiment.

In step S311 of FIG. 3, first dielectric layer 101 is formed on first conductive layer 110, as shown in FIG. 4A. As stated above, the first conductive layer 110 may be a solid conductive layer, one or more conductors or a pattern of conductors and other circuitry layer. When the first conductive layer 110 includes an actual pattern, a masking and etching process is performed to remove portions of the conductive material to form the pattern, either before or after deposition of the first dielectric layer 101. For example, the pattern may be formed after the first dielectric layer 101 is disposed on the first conductive layer 110 by flipping the combined layers (immediately after formation of the first dielectric layer 101 or ultimately after formation of the third conductive layer 130, shown in FIG. 4E), forming a photoresist pattern on the conductive material, etching the conductive material through openings in the photoresist pattern, e.g., using a hydrochloric acid and hydrogen peroxide etch, for example, and then removing the photoresist pattern, leaving a patterned first conductive layer 110, as would be apparent to one of ordinary skill in the art. Alternatively, the pattern formation may be an additive process in which the conductive material is pattern plated on top of a seed layer on which a dry film pattern has been applied. The dry film is then stripped, and the seed layer is etched to create the pattern. An example of an additive process is described below with reference to steps S313 to S316.

In step S312, a seed layer 421 is then formed on the first dielectric layer 101, also shown in FIG. 4A. The seed layer 421 may comprise a thin layer (e.g., about 2 μm) of copper foil applied to the top surface of the first dielectric layer 101, for example. The copper foil may be applied using chemical vapor deposition (CVD) or sputtering, or the 2 μm copper foil may be laminated on, for example.

In step S313, a dry film pattern 422 is formed on the seed layer 421 using photo-lithography, for example, where the dry film pattern 422 includes opening 423 to enable eventual formation of the conductor core 122. In step S314, copper is plated up on exposed surface(s) of the seed layer 421 through the opening 423, as shown in FIG. 4C, forming preliminary conductor core 424. The dry film pattern is removed in step S315 leaving an exposed preliminary conductor core 424 combined with the seed layer 421, as shown in FIG. 4D. The dry film pattern may be removed by chemical etching, for example. The combined preliminary conductor core 424 and seed layer 421 are patterned and etched in step S316 to form conductor core 122 (of wrapped conductor 120), as shown in FIG. 4E. Of course, other application processes may be incorporated to form the conductor core 122 without departing from the scope of the present teachings.

In step 317, conductive wrap 125 is applied to exposed surfaces (top and sides) of the conductor core 122, as shown in FIG. 4F. For example, the conductive wrap 125 may be silver, as discussed above, and the silver may be applied using an electroplating process, such as a silver immersion, although other application processes may be incorporated, such as an electroless plating process, for example. The conductor core 122 with the conductive wrap 125 provides the wrapped conductor 120, as discussed above. Application of the conductive wrap 125 minimizes or eliminates oxidation of the copper conductive core 122, and improves conductivity and integrity of the embedded wrapped conductor 120.

Second dielectric layer 102 is formed on the first dielectric layer 101 and the conductive wrap 125 of the wrapped conductor 120 in step 318, as shown in FIG. 4G, to form substrate 105. The wrapped conductor 120 is thereby embedded within the substrate 105, between the first and second dielectric layers 101 and 102. The second dielectric layer 102 may be formed using CVD, for example, although other application processes may be incorporated. In order to enhance adhesion of the second dielectric layer 102 (lamination) to the wrapped conductor 120, the exposed surfaces of the conductive wrap 125 (e.g., silver) may be roughened prior to application of the second dielectric layer 102.

In step 319, third conductive layer 130 is formed on the second dielectric layer 102, also as shown in FIG. 4G. When the third conductive layer 130 includes an actual pattern, a masking and etching process is performed to remove portions of the conductive material to form the pattern after deposition of a layer of conductive material corresponding to the third conductive layer 130. For example, the pattern may be provided by forming a photoresist pattern on the layer of conductive material, etching the conductive material through openings in the photoresist pattern, e.g., using a hydrochloric acid and hydrogen peroxide etch, for example, and then removing the photoresist pattern, leaving a patterned third conductive layer 130, as would be apparent to one of ordinary skill in the art. Alternatively, the pattern formation may be an additive process, as discussed above. The end product in FIG. 4G is thus the same as that shown in FIG. 1.

FIG. 5 is a cross-sectional view of a PCB including a partially embedded wrapped conductor, according to a representative embodiment.

Referring to FIG. 5, PCB 500 includes a substrate 505 having only a single dielectric layer 502 formed over a first (partially embedded) wrapped conductor 520. A (top) conductive layer 530 is formed on the substrate 505. In particular, the wrapped conductor 520 is formed on a top surface of a sacrificial layer (not shown), the dielectric layer 502 is formed on top surfaces of the wrapped conductor 520 and the sacrificial layer, and the conductive layer 530 is formed on the top surface of the dielectric layer 502 (which is also the top surface of the substrate 505). The sacrificial layer may be formed of phosphosilicate glass (PSG), for example, which is subsequently released following formation of the conductive layer 530, thereby exposing a bottom surface of the wrapped conductor 520. Although the conductive layer 530 is referred to as a “layer,” it is understood that this term may include a conductive “pattern,” indicating the presence of multiple conductors, traces, pads and/or other circuitry, without departing from the scope of the present teachings. Likewise, for purposes of illustration and ease of description, the wrapped conductor 520 is shown as a single conductor, although it is understood that the wrapped conductor 520 may include multiple conductors and/or a conductive “pattern,” as mentioned above, without departing from the scope of the present teachings.

The wrapped conductor 520 is partially embedded within the substrate 505 in that at least the top and side surfaces in the cross-sectional view are covered by the dielectric layer 502, while the bottom surface of the wrapped conductor 520 (corresponding to the conductor core 522, discussed below) is exposed. The wrapped conductor 520 enables transmission of an RF signal, for example.

In various embodiments, the dielectric layer 502 and the wrapped conductor 520 may be formed of the same materials discussed above with regard to the first and second dielectric layers 101 and 102, and the first and third conductor layers 110 and 130 in FIG. 1. Also, as discussed above with regard to the wrapped conductor 120, the wrapped conductor 520 includes a conductor core 522 and a conductive wrap 525 surrounding the core 522 on three sides.

The conductive wrap 525 has a lower resistivity (p) than the conductor core 522, so that the majority of the RF power is conducted through the conductive wrap 525, as opposed to the conductor core 522. For example, the conductor core 522 may be formed of copper, which has a resistivity of about 1.68×10⁻⁸ ohm-meter, and the conductive wrap 525 may be formed of silver, which has a resistivity of about 1.59×10⁻⁸ ohm-meter. In the depicted embodiment, thickness 522′ of the copper core 522 is approximately 15 μm, and thickness 525′ of the silver conductive wrap 525 is approximately 1.5 μm. This thickness enables propagation of substantially all RF energy through the silver conductive wrap 125 for RF signals having a operating frequency of about 16 GHz and above, as discussed above with reference to FIG. 2. Also, for example, thickness 502′ of the dielectric layer 502 formed above the wrapped conductor 520 may be approximately 40 μm. Of course, the thicknesses and/or materials of the various layers may vary to provide unique benefits for any particular situation or to meet application specific design requirements of various implementations, as would be apparent to one skilled in the art.

In various embodiments, the thickness of the conductive wrap 525 is determined based on the portion of RF energy of the RF signal to be propagated through the conductive wrap 525 (as opposed to the conductor core 522) of the wrapped conductor 520. For example, in a representative embodiment, the thickness of the conductive wrap 525 is determined such that about 98 percent of the RF energy is propagated through three skin depths of the material forming the conductive wrap 525, as discussed above with regard to the conductive wrap 125.

In various embodiments, the thicknesses and/or materials of the various layers may vary to provide unique benefits for any particular situation or to meet application specific design requirements of various implementations, as would be apparent to one skilled in the art.

The various components, materials, structures and parameters are included by way of illustration and example only and not in any limiting sense. In view of this disclosure, those skilled in the art can implement the present teachings in determining their own applications and needed components, materials, structures and equipment to implement these applications, while remaining within the scope of the appended claims.

1. A printed circuit board (PCB), comprising:
a wrapped conductor configured to enable transmission of a radio frequency (RF) signal, the wrapped conductor comprising a conductor core and a conductive wrap disposed on top and side surfaces of the conductor core; and
a top dielectric layer disposed on the conductive wrap of the wrapped conductor, at least partially embedding the wrapped conductor,
wherein resistivity of the conductive wrap is less than resistivity of the conductor core, such that a majority of RF power of the RF signal is propagated through the conductive wrap.

2. The PCB of claim 1, wherein a bottom surface of the conductor core is exposed at a bottom surface of the top dielectric layer.

3. The PCB of claim 1, further comprising:
a bottom dielectric layer, wherein the wrapped conductor is disposed between the bottom dielectric layer and the top dielectric layer, fully embedding the wrapped conductor.

4. The PCB of claim 3, further comprising:
a bottom conductive layer on which the bottom dielectric layer is disposed; and
a top conductive layer disposed on the top dielectric layer.

5. The PCB of claim 1, wherein the conductor core comprises copper and the conductive wrap comprises silver.

6. The PCB of claim 5, wherein the silver conductive wrap comprises a roughened surface, which improves adhesion of the top dielectric layer to the wrapped conductor.

7. The PCB of claim 5, wherein the silver conductive wrap has a thickness that enables substantially all RF energy of the RF signal to propagate through silver material forming the silver wrap.

8. The PCB of claim 7, wherein the thickness of the silver conductive wrap is approximately three skin depths of the silver material, the skin depth depending on an operating frequency of the RF signal and the resistivity of the conductive wrap.

9. The PCB of claim 8, wherein the RF signal operates over a range of potential frequencies, and the operating frequency for determining the skin depth is the lowest frequency of the range of potential frequencies.

10. The PCB of claim 5, wherein the silver conductive wrap has a thickness of about 0.5 μm and the copper conductor core has a thickness of about 15 μm.

11. The PCB of claim 5, wherein the silver conductive wrap is plated onto the copper conductor core.

12. The PCB of claim 3, wherein at least one of the first dielectric layer and the second dielectric layer comprise an organic material.

13. A build-up substrate of a printed circuit board (PCB), comprising:
a first dielectric layer;
a copper conductor core disposed on a top surface of the first dielectric layer;
a plated silver conductive wrap disposed on top and side surfaces of the copper conductor core, the plated silver conductive wrap being configured to transmit a radio frequency (RF) signal; and
a second dielectric layer disposed on exposed portions of the top surface of the first dielectric layer and the plated silver conductive wrap,
wherein a majority of RF power of the RF signal is propagated through the plated silver conductive wrap.

14. The build-up substrate of claim 13, wherein a thickness of the plated silver conductive wrap is approximately three skin depths of silver, the skin depth being a function of an operating frequency of the RF signal.

15. The build-up substrate of claim 14, wherein the thickness of the plated silver conductive wrap is determined such that approximately 98 percent of the RF power is propagated through the plated silver conductive wrap at the operating frequency of the RF signal.

16. The build-up substrate of claim 13, wherein the plated silver conductive wrap adheres the copper conductor core to the top dielectric layer.

17. The build-up substrate of claim 15, wherein the copper conductor core has an impedance of about 50 ohms.

18. A method of fabricating a printed circuit board (PCB) having an embedded wrapped conductor, the method comprising:
forming a seed layer on a first dielectric layer;
forming a copper layer on the seed layer;
patterning and etching the copper layer and the seed layer to form a copper conductor core;
plating silver to exposed surfaces of the copper conductor; and
forming a second dielectric layer on the first dielectric layer and the plated silver wrap to form the embedded wrapped conductor.

19. The method of claim 18, wherein the plated silver wrap is formed to have a thickness of approximately three skin depths of silver to enable substantially all radio frequency (RF) energy of an RF signal to propagate through the corresponding plated silver wrap.

20. The method of claim 15, wherein plating the silver to the exposed surfaces of the copper conductor core comprises application of one of an immersion silver process, an electroplating process, or an electroless plating process.
